(19) United States
(12) Patent Application Publication
(10) Pub. No.: US 2025/0380596 A1
(43) Pub. Date: Dec. 11, 2025

(54) DISPLAY DEVICE, METHOD OF MANUFACTURING DISPLAY DEVICE, AND ELECTRONIC DEVICE INCLUDING DISPLAY DEVICE

(71) Applicant: Samsung Display Co., Ltd., Yongin-Si (KR)

(72) Inventors: Ye Eun KANG, Yongin-si (KR); Jae Hyun LEE, Yongin-si (KR); Sung Won KIM, Yongin-si (KR); Seung Rae KIM, Yongin-si (KR); Seo Hee LEE, Yongin-si (KR)

(21) Appl. No.: 19/026,367

(22) Filed: Jan. 17, 2025

(30) Foreign Application Priority Data
Jun. 5, 2024 (KR) 10-2024-0073733

(51) Int. Cl. H10K 59/80; H10K 59/12; H10K 59/122; H10K 59/123

(52) U.S. Cl. CPC H10K 59/873; H10K 59/1201; H10K 59/123; H10K 59/122

(57) ABSTRACT

A display device is disclosed that includes: a substrate including a display area and a non-display area, a pixel circuit layer disposed on the substrate, and a support structure disposed on the pixel circuit layer in the non-display area. The support structure includes a first support pattern, a second support pattern facing the first support pattern, and a third support pattern disposed between the first support pattern and the second support pattern.

### CROSS-REFERENCE TO RELATED APPLICATION(S)

The application claims priority to Korean Patent Application No. 10-2024-0073733 filed on Jun. 5, 2024 and all the benefits accruing therefrom under 35 U.S.C. § 119, the content of which is herein incorporated by reference.

### BACKGROUND

### 1. Field

The present disclosure relates to a display device, a method of manufacturing the display device, and an electronic device including the display device.

### 2. Description of the Related Art

With the development of information technology, a display device's role as a connection medium between a user and information is becoming increasingly important. As a consequence, the demand for display devices such as a liquid crystal display device and an organic light emitting display device is on the rise.

### SUMMARY

Embodiments may provide a display device, a method of manufacturing the display device, and an electronic device including the display device, which can prevent a stab phenomenon of a mask.

According to an embodiment, a display device includes: a substrate including a display area and a non-display area, a pixel circuit layer disposed on the substrate, and a support structure disposed on the pixel circuit layer in the non-display area. The support structure may include a first support pattern, a second support pattern facing the first support pattern, and a third support pattern disposed between the first support pattern and the second support pattern.

In an embodiment, the display device may further include a first dam structure, a second dam structure, and a third dam structure disposed on the pixel circuit layer in the non-display area and spaced apart from each other.

In an embodiment, the first dam structure may include a first dam lower pattern, the second dam structure may include a second dam lower pattern and a first dam upper pattern disposed on the second dam lower pattern, and the third dam structure may include a third dam lower pattern and a second dam upper pattern disposed on the third dam lower pattern.

In an embodiment, the display device may further include a via layer disposed on the pixel circuit layer in the display area, an anode disposed on the via layer and extending through a portion of the pixel circuit layer and the via layer, and a pixel defining layer disposed on a portion of the anode and the via layer.

In an embodiment, the first, second, and third dam lower patterns and the first support pattern may be formed of the same material as the via layer, the first and second dam upper patterns and the second support pattern may be formed of the same material as the pixel defining layer, and the third support pattern may be formed of the same material as the anode.

In an embodiment, a thickness of the support structure may be greater than a thickness of the first, second, and third dam structures.

In an embodiment, a thickness of the first support pattern may be greater than a thickness of the first, second, and third dam lower patterns.

In an embodiment, a width of the second support pattern may be less than a width of the first support pattern.

In an embodiment, a width of the second support pattern may be greater than a width of the first support pattern.

In an embodiment, the second support pattern may surround the first support pattern and the third support pattern.

In an embodiment, the second dam structure may further include a first dam center pattern disposed between the second dam lower pattern and the first dam upper pattern, and the third dam structure may further include a second dam center pattern disposed between the third dam lower pattern and the second dam upper pattern.

In an embodiment, a thickness of the support structure may be greater than a thickness of the first dam structure and may be equal to a thickness of the second and third dam structures.

In an embodiment, a thickness of the first support pattern may be greater than a thickness of the first dam lower pattern and may be equal to a thickness of the second and third lower patterns.

In an embodiment, the first and second dam center patterns may be formed of the same material as the anode.

According to an embodiment, a method of manufacturing a display device includes: patterning a via layer that is on a pixel circuit layer in a display area, and patterning a first dam lower pattern, a second dam lower pattern, a third dam lower pattern, and a first support pattern on the pixel circuit layer in a non-display area, patterning a portion of the pixel circuit layer and an anode extending through the via layer on the via layer and patterning a third support pattern on the first support pattern, removing a first photoresist on the anode and a second photoresist on the third support pattern, and patterning a pixel defining layer on a portion of the anode and the via layer, patterning a first dam upper pattern on the second dam lower pattern, patterning a second dam upper pattern on the third dam lower pattern, and patterning a second support pattern on the third support pattern.

In an embodiment, after removing the first photoresist and the second photoresist, a thickness of the first support pattern may be greater than a thickness of the first, second, and third dam lower patterns.

In an embodiment, a width of the second support pattern may be less than a width of the first support pattern.

In an embodiment, a width of the second support pattern may be greater than a width of the first support pattern.

In an embodiment, the second support pattern may surround the first support pattern and the third support pattern.

In an embodiment, the method may further include patterning a first dam center pattern positioned between the second dam lower pattern and the first dam upper pattern and patterning a second dam center pattern positioned between the third dam lower pattern and the second dam upper pattern, and after removing the first photoresist and the second photoresist, a thickness of the first support pattern may be greater than a thickness of the first dam lower pattern and may be equal to a thickness of the second and third dam lower patterns.

According to an embodiment, an electronic device includes: a processor to provide input image data and a display device to display an image based on the input image data. The display device may include a substrate including a display area and a non-display area, a pixel circuit layer disposed on the substrate, and a support structure disposed on the pixel circuit layer in the non-display area. The support structure may include a first support pattern, a second support pattern facing the first support pattern, and a third support pattern disposed between the first support pattern and the second support pattern.

According to embodiments of the disclosure, a thickness of a support structure supporting a mask may be maintained the same during a manufacturing process, thereby preventing a stab phenomenon of a mask.

### BRIEF DESCRIPTION OF THE DRAWINGS

The above and other features of embodiments of the present disclosure will become more apparent by describing in further detail embodiments thereof with reference to the accompanying drawings, in which:

FIG. 1 is a block diagram illustrating a display device according to an embodiment.

FIG. 2 is a block diagram illustrating a sub-pixel according to an embodiment.

FIG. 3 is a plan view illustrating a display panel according to an embodiment.

FIG. 4 is a cross-sectional view schematically illustrating a display panel according to an embodiment.

FIG. 5 is a cross-sectional view taken along line I-I′ of FIG. 3 according to an embodiment.

FIG. 6 is a cross-sectional view schematically illustrating a defect due to a thickness decrease of a support structure.

FIG. 7 is a flowchart illustrating a method of manufacturing a display device according to an embodiment.

FIGS. 8 to 12 are cross-sectional views illustrating a method of manufacturing a display device according to an embodiment.

FIG. 13 is a cross-sectional view taken along line I-I′ of FIG. 3 according to an embodiment.

FIG. 14 is a cross-sectional view taken along line I-I′ of FIG. 3 according to an embodiment.

FIG. 15 is a block diagram of an electronic device according to an embodiment.

FIG. 16 shows schematic views of various embodiments of an electronic device.

### DETAILED DESCRIPTION OF THE EMBODIMENT

Hereinafter, a preferred embodiment according to the disclosure is described in detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiment described herein. However, the embodiment described herein is provided to describe in detail enough to easily implement the technical spirit of the disclosure to those skilled in the art to which the disclosure belongs.

Throughout the specification, a portion being “connected” to another portion includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes” another component, the case means that the portion may further include another component without excluding a second component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XY, YZ, and ZZ). Here, “and/or” includes all combinations of one or more of corresponding configurations.

Here, terms such as “first” and “second” may be used to describe various components, but these components are not limited to any order or priority by these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions—“on” and “under.” In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

Hereinafter, embodiments will be described in detail with reference to the accompanying drawings.

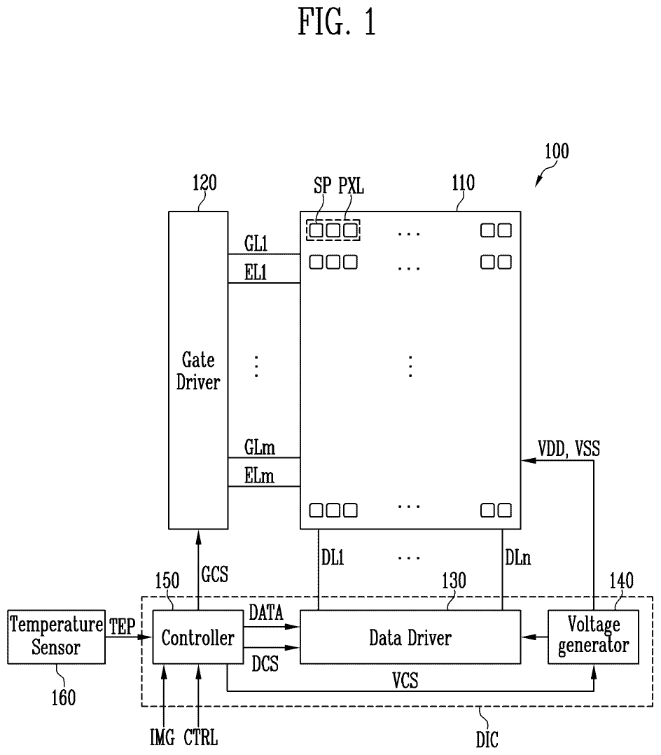

FIG. 1 is a block diagram illustrating a display device according to an embodiment.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color such as red, green, blue, cyan, magenta, or yellow. Two or more sub-pixels among the sub-pixels SP may configure one pixel PXL. For example, as shown in FIG. 1, three sub-pixels may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting the gate signals in synchronization with a timing at which data signals are applied, and the like.

In embodiments, first to m-th emission control lines EL1 to ELm connected to the sub-pixels SP of the row direction may be further provided. In this case, the gate driver 120 may include an emission control driver configured to control the first to m-th emission control lines EL1 to Elm, and the emission control driver may operate under control of the controller 150.

The gate driver 120 may be disposed on one side of the display panel 110. However, embodiments are not limited thereto. For example, the gate driver 120 may be divided into two or more physically and/or logically divided drivers, and such drivers may be disposed on two opposite sides of the display panel 110. As described above, the gate driver 120 may be disposed around the display panel 110 in various shapes according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the first to n-th data lines DL1 to DLm. Accordingly, the corresponding sub-pixels SP may generate light corresponding to the data signals. Accordingly, an image is displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device 100. For example, the voltage generator 140 may be configured to generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a predetermined reference voltage may be applied to the first to n-th data lines DL1 to DLn, and the voltage generator 140 may generate such a reference voltage.

The controller 150 controls overall operations of the display device 100. The controller 150 receives input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, and the controller 150 may be provided as a component distinguished from the driver integrated circuit DIC.

The display device 100 may include at least one temperature sensor 160. The temperature sensor 160 is configured to sense a temperature around the temperature sensor 160 and generate temperature data TEP indicating the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust a luminance of the image output from the display panel 110 in response to the temperature data TEP. For example, the controller 150 may control the data signals and the first and second power voltages VDD and VSS by controlling components such as the data driver 130 and/or the voltage generator 140.

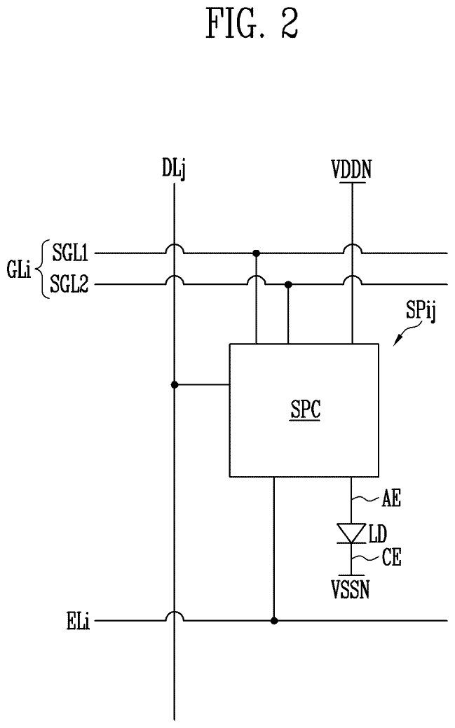

FIG. 2 is a block diagram illustrating a sub-pixel according to an embodiment. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD is connected between a first power voltage node VDDN and a second power voltage node VSSN. At this time, the first power voltage node VDDN is a node that transmits the first power voltage VDD of FIG. 1, and the second power voltage node VSSN is a node that transmits the second power voltage VSS of FIG. 1.

An anode AE of the light emitting element LD may be connected to the first power voltage node VDDN through the sub-pixel circuit SPC, and a cathode CE of the light emitting element LD may be connected to the second power voltage node VSSN. For example, the anode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light emitting element LD according to signals received through such signal lines.

The sub-pixel circuit SPC may operate in response to a gate signal received through the i-th gate line GLi. The i-th gate line GLi may include one or more sub gate lines. In embodiments, as shown in FIG. 2, the i-th gate line GLi may include first and second sub gate lines SGL1 and SGL2. The sub-pixel circuit SPC may operate in response to gate signals received through the first and second sub gate lines SGL1 and SGL2. As described above, when the i-th gate line GLi includes two or more sub gate lines, the sub-pixel circuit SPC may operate in response to gate signals received through the corresponding sub gate lines.

The sub-pixel circuit SPC may operate in response to an emission control signal received through the i-th emission control line ELi. In embodiments, the i-th emission control line ELi may include one or more sub emission control lines. When the i-th emission control line ELi includes two or more sub emission control lines, the sub-pixel circuit SPC may operate in response to emission control signals received through the corresponding sub emission control lines.

The sub-pixel circuit SPC may receive a data signal through the j-th data line DLj. The sub-pixel circuit SPC may store a voltage corresponding to the data signal in response to at least one of the gate signals received through the first and second sub gate lines SGL1 and SGL2. The sub-pixel circuit SPC may adjust a current flowing from the first power voltage node VDDN to the second power voltage node VSSN through the light emitting element LD according to the stored voltage, in response the emission control signal received through the i-th emission control line ELi. Accordingly, the light emitting element LD may generate light of a luminance corresponding to the data signal.

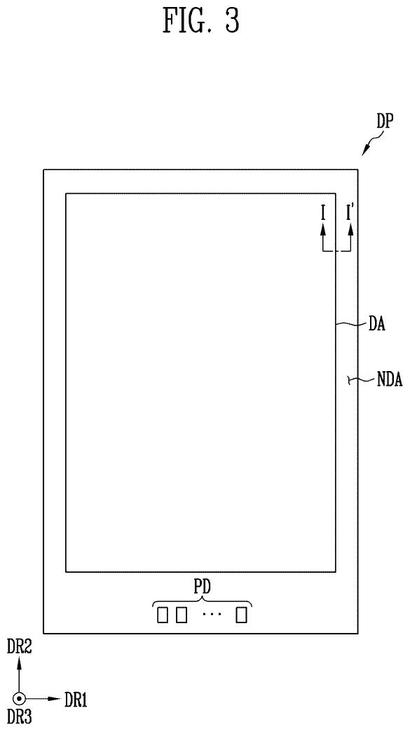

FIG. 3 is a plan view illustrating a display panel according to an embodiment.

Referring to FIG. 3, an embodiment DP of the display panel 110 of FIG. 1 may include a display area DA and a non-display area NDA. The display panel DP displays an image through the display area DA. The non-display area NDA is disposed around the display area DA.

The sub-pixels SP (refer to FIG. 1) may be disposed in the display area DA. The sub-pixels SP may be arranged in a matrix shape along a first direction DR1 and a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILE™ shape. The first direction DR1 may be a row direction, and the second direction DR2 may be a column direction.

A component for controlling the sub-pixels SP may be disposed in the non-display area NDA. For example, lines connected to the sub-pixels SP, such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150, and the temperature sensor 160 of FIG. 1 may be integrated in the non-display area NDA. In embodiments, the gate driver 120 of FIG. 1 may be mounted on the display panel DP and may be disposed in the non-display area NDA. In other embodiments, the gate driver 120 may be implemented as an integrated circuit separated from the display panel DP. In embodiments, the temperature sensor 160 may be disposed in the non-display area NDA to sense a temperature of the display panel DP.

Pads PD may be disposed in the non-display area NDA. The pads PD may be electrically connected to the sub-pixels SP through lines. For example, the pads PD may be connected to the sub-pixels SP through the first to n-th data lines DL1 to DLn.

The pads PD may interface the display panel DP to other components of the display device 100 (refer to FIG. 1). In embodiments, voltages and signals necessary for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In embodiments, a circuit board may be electrically connected to the pads PD using a conductive adhesive member such as an anisotropic conductive film. At this time, the circuit board may be a flexible circuit board (FPCB) or a flexible film having a flexible material. The driver integrated circuit DIC may be mounted on the circuit board to be electrically connected to the pads PD.

In embodiments, the display area DA may have various shapes. The display area DA may have a closed loop shape including straight and/or curved sides. For example, the display area DA may have shapes such as a polygon, a circle, a semicircle, and an ellipse.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate SUB may include materials having a flexible property.

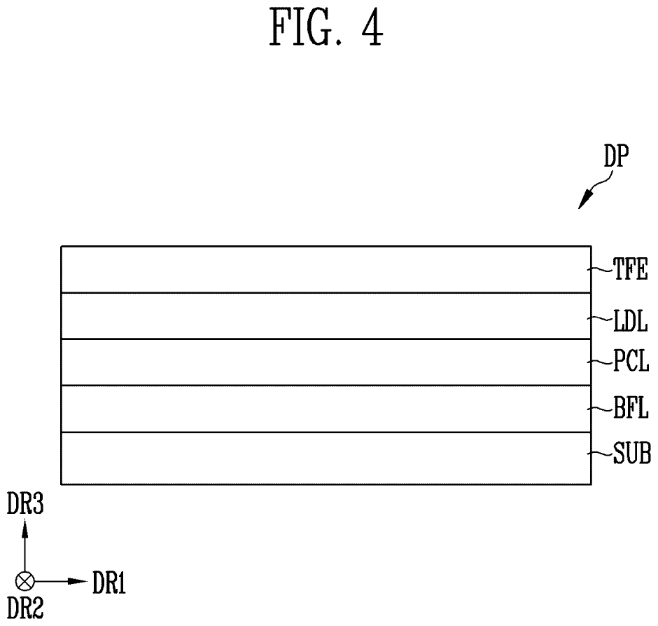

FIG. 4 is a cross-sectional view schematically illustrating a display panel according to an embodiment.

Referring to FIG. 4, the display panel DP may include a substrate SUB, a buffer layer BFL, a pixel circuit layer PCL, a light emitting element layer LDL, and an encapsulation layer TFE.

The substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In still other embodiments, the substrate SUB may include a polyimide (PI) substrate.

The buffer layer BFL may be disposed on the substrate SUB. The buffer layer BFL may be an inorganic insulating layer including an inorganic material. The buffer layer BFL may include at least one of silicon nitride (SiNₓ), silicon oxide (SiOₓ), silicon oxynitride (SiOₓN_{y}), and aluminum oxide (AlOₓ). The buffer layer BFL may be provided as a single layer, but may also be provided as multiple layers of at least double layers or more. When the buffer layer BFL is provided as multiple layers, each layer may be formed of the same material or may be formed of different materials. The buffer layer BFL may be omitted according to a material, a process condition, and the like of the substrate SUB.

The pixel circuit layer PCL may be disposed on the buffer layer BFL. The pixel circuit layer PCL may include insulating layers and conductive patterns disposed between the insulating layers. The conductive patterns of the pixel circuit layer PCL may function as at least a portion of circuit elements, lines, and the like.

The circuit elements may include the sub-pixel circuit SPC (refer to FIG. 2) for each of the sub-pixels SP (refer to FIG. 1). The sub-pixel circuit SPC may include transistors and one or more capacitors. Each transistor may include a semiconductor portion including a source area, a drain area, and a channel area, and a gate electrode overlapping the semiconductor portion.

The lines of the pixel circuit layer PCL may include signal lines connected to each of the sub-pixels SP, for example, a gate line, an emission control line, a data line, and the like. The lines may further include a line connected to the first power voltage node VDDN of FIG. 2. In addition, the lines may further include a line connected to the second power voltage node VSSN of FIG. 2.

The light emitting element layer LDL may be disposed on the pixel circuit layer PCL. The light emitting element layer LDL may include the light emitting element LD (refer to FIG. 2) that emits light. A detailed description of the light emitting element layer LDL is described later.

The encapsulation layer TFE may be disposed on the light emitting element layer LDL. The encapsulation layer TFE may prevent an impurity, moisture, or the like from penetrating into the light emitting element layer LDL. The encapsulation layer TFE may include a structure in which one or more inorganic layers and one or more organic layers are alternately stacked. A detailed description of the encapsulation layer TFE is described later.

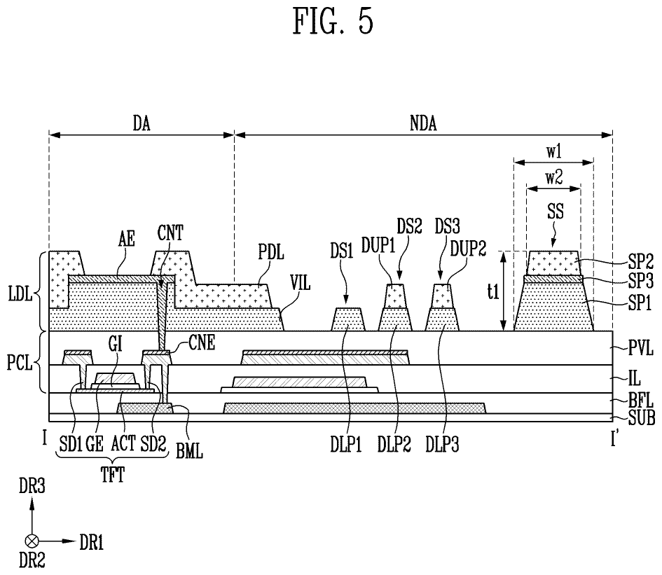

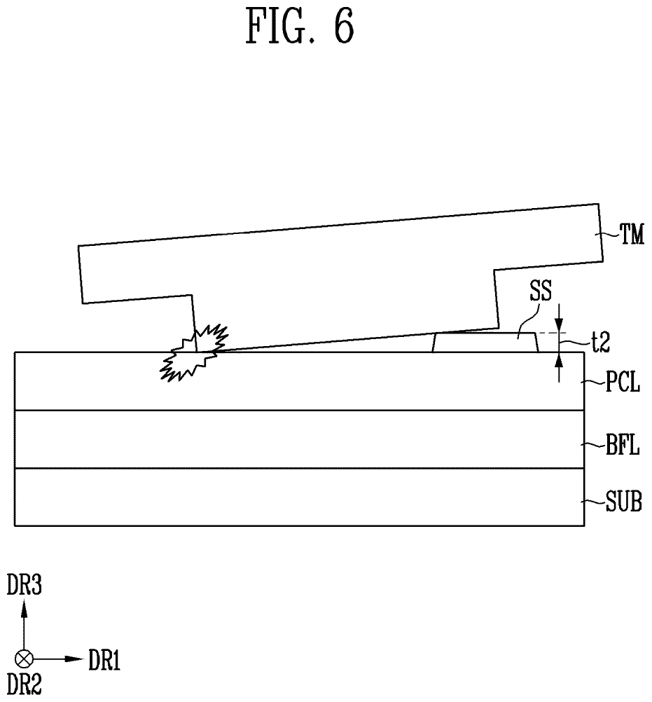

FIG. 5 is a cross-sectional view taken along line I-I′ of FIG. 3 according to an embodiment. FIG. 6 is a cross-sectional view schematically illustrating a defect due to a thickness decrease of a support structure.

Referring to FIG. 5, the substrate SUB may include the display area DA and the non-display area NDA.

A lower metal layer BML may be disposed on the substrate SUB. For example, the lower metal layer BML may be disposed on the substrate SUB in the display area DA. The lower metal layer BML may be a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but embodiments are not limited thereto.

The buffer layer BFL may be disposed on the lower metal layer BML and the substrate SUB. For example, the buffer layer BFL may be disposed entirely throughout the display area DA and the non-display area NDA to surround the lower metal layer BML.

The pixel circuit layer PCL may be disposed on the buffer layer BFL. The pixel circuit layer PCL may include an active pattern ACT, a gate insulating layer GI, a gate electrode GE, an interlayer insulating layer ILD, first and second electrodes SD1 and SD2, a connection electrode CNE, and a passivation layer PVL.

The active pattern ACT may be disposed on the buffer layer BFL. For example, the active pattern ACT may be disposed on the buffer layer BFL in the display area DA. The active pattern ACT may partially overlap the lower metal layer BML in a third direction DR3 (or a thickness direction). The active pattern ACT may include one of a low temperature poly silicon (LTPS) semiconductor, an oxide semiconductor, and a metal oxide semiconductor.

The active pattern ACT may include a channel area, a first contact area connected to one end of the channel area, and a second contact area connected to another end of the channel area. The channel area, the first contact area, and the second contact area may be a semiconductor layer that is not doped with an impurity or is doped with an impurity. For example, the first contact area and the second contact area may be a semiconductor layer doped with an impurity, and the channel area may be a semiconductor layer that is not doped with an impurity. The impurity may be a p-type impurity or an n-type impurity. One of the first and second contact areas may be a source area and the other may be a drain area.

The gate insulating layer GI may be disposed on the active pattern ACT. The gate insulating layer GI may be an inorganic layer (or an inorganic insulating layer) including an inorganic material. For example, the gate insulating layer GI may include at least one of silicon nitride (SiNₓ), silicon oxide (SiOₓ), silicon oxynitride (SiOₓN_{y}), and aluminum oxide (AlOₓ), but embodiments are not limited thereto. The gate insulating layer GI may be formed of an organic layer (or an organic insulating layer) including an organic material. The gate insulating layer GI may be provided as a single layer, but may also be provided as multiple layers of at least double layers or more.

The gate electrode GE may be disposed on the gate insulating layer GI. The gate electrode GE may overlap the channel area of the active pattern ACT. The gate electrode GE may include one selected from a group consisting of copper (Cu), molybdenum (Mo), tungsten (W), aluminum neodymium (AlNd), titanium (Ti), aluminum (Al), silver (Ag), and an alloy thereof, or a mixture thereof, but embodiments are not limited thereto. The gate electrode GE may be provided as a single layer, but may also be provided as multiple layers at least double layers or more.

The interlayer insulating layer IL may be disposed on the gate electrode GE and the buffer layer BFL. For example, the interlayer insulating layer IL may be disposed entirely throughout the display area DA and the non-display area NDA to surround the gate electrode GE, the gate insulating layer GI, and the active pattern ACT. The interlayer insulating layer IL may include the same material as the gate insulating layer GI or may include one or more materials selected from the materials exemplified as the configuration material of the gate insulating layer GI.

The first and second electrodes SD1 and SD2 may be disposed on the interlayer insulating layer IL. The first electrode SD1 may be connected to the first contact area of the active pattern ACT through a contact hole extending through the interlayer insulating layer IL. When the first contact area is the source area, the first electrode SD1 may be a source electrode. When the first contact area is the drain area, the first electrode SD1 may be a drain electrode.

The second electrode SD2 may be connected to the second contact area of the active pattern ACT through a contact hole extending through the interlayer insulating layer IL. In addition, the second electrode SD2 may be connected to the lower metal layer BML through a contact hole extending through the interlayer insulating layer IL and the buffer layer BFL. When the second contact area is the drain area, the second electrode SD2 may be a drain electrode. When the second contact area is the source area, the second electrode SD2 may be a source electrode.

The first and second electrodes SD1 and SD2 may include the same material as the gate electrode GE or may include one or more materials selected from the materials exemplified as the configuration material of the gate electrode GE.

The active pattern ACT, the gate electrode GE, and the first and second electrodes SD1 and SD2 described above may configure a thin film transistor TFT. The thin film transistor TFT may be one of the transistors of the sub-pixel circuit SPC (refer to FIG. 2).

The connection electrode CNE may be disposed on the first and second electrodes SD1 and SD2. The connection electrode CNE may include one selected from a group consisting of titanium (Ti), aluminum (Al), silver (Ag), and an alloy thereof, or a mixture thereof, but embodiments are not limited thereto.

The passivation layer PVL may be disposed on the connection electrode CNE and the interlayer insulating layer IL. For example, the passivation layer PVL may be disposed entirely throughout the display area DA and the non-display area NDA to surround the connection electrode CNE and the first and second electrodes SD1 and SD2.

The passivation layer PVL may be an inorganic layer (or an inorganic insulating layer) including an inorganic material or an organic layer (or an organic insulating layer) including an organic material. For example, the inorganic layer may include at least one of silicon oxide (SiOₓ), silicon nitride (SiNₓ), silicon oxynitride (SiOₓN_{y}), and aluminum oxide (AlOₓ). For example, the organic layer may include at least one of acrylic resin (polyacrylates resin), epoxy resin, phenolic resin, polyamides resin, polyimides resin, unsaturated polyester resin, poly-phenylene ethers resin, poly-phenylene sulfides resin, and benzocyclobutene resin. The passivation layer PVL may be provided as a single layer, but may also be provided as multiple layer of at least double layers or more.

The light emitting element layer LDL may be disposed on the pixel circuit layer PCL. The light emitting element layer LDL may include the via layer VIL, an anode AE, the pixel defining layer PDL, first, second, and third dam lower patterns DLP1, DLP2, DLP3, first and second dam upper patterns DUP1 and DUP2, and first, second, and third support patterns SP1, SP2, SP3.

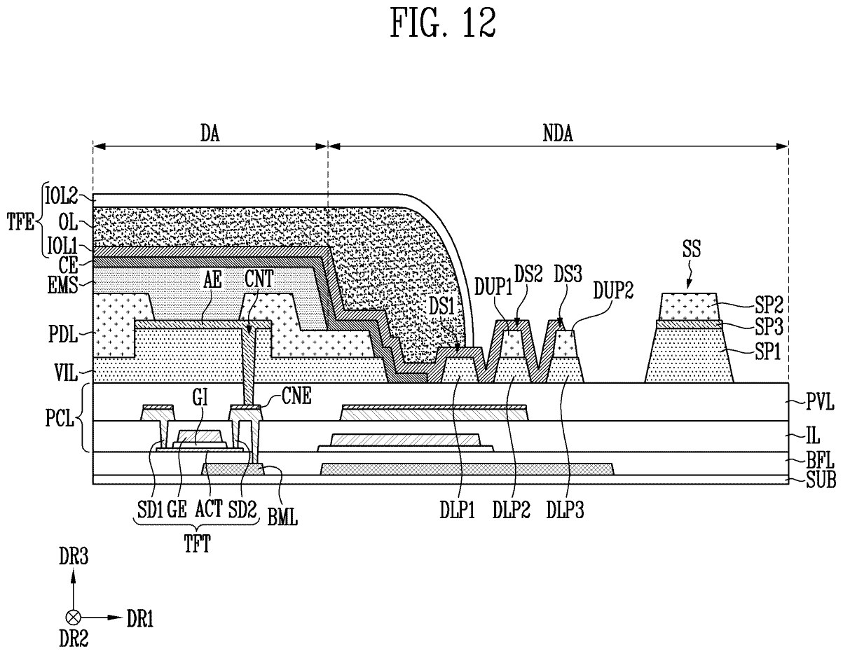

For convenience of description, some configurations of the light emitting element layer LDL are shown in FIG. 5, but embodiments are not limited thereto. For example, the light emitting element layer LDL may further include a light emitting structure EMS and a cathode CE shown in FIG. 12.

The via layer VIL may be disposed on the passivation layer PVL. For example, the via layer VIL may be disposed on the passivation layer PVL in the display area DA. The via layer VIL may be partially disposed on the passivation layer PVL in the non-display area NDA. The via layer VIL may include the same material as the passivation layer PVL or may include one or more materials selected from the material exemplified as the configuration material of the passivation layer PVL. In embodiments, the via layer VIL may be an organic layer formed of an organic material.

The anode AE may be disposed on the via layer VIL. For example, the anode AE may be disposed on the via layer VIL in the display area DA. The anode AE may be connected to the connection electrode CNE through a contact hole CNT extending through the via layer VIL and the passivation layer PVL. That is, the anode AE may be electrically connected to the second electrode SD2 through the contact hole CNT and the connection electrode CNE.

The anode AE may include a transparent conductive material. For example, the anode AE may include at least one of indium tin oxide (ITO), indium zinc oxide (IZO), zinc oxide (ZnO), indium gallium zinc oxide (IGZO), and indium tin zinc oxide (ITZO). However, embodiments are not limited thereto, and the anode AE may include titanium nitride.

The pixel defining layer PDL may be disposed on the anode AE and the via layer VIL. The pixel defining layer PDL may include an opening that partially exposes the anode AE. That is, the pixel defining layer PDL may be partially disposed on the anode AE. The pixel defining layer PDL may include a plurality of inorganic insulating layers. Each of the plurality of inorganic insulating layers may include at least one of silicon oxide (SiOₓ) and silicon nitride (SiNₓ). For example, the pixel defining layer PDL may include first, second, and third inorganic insulating layers sequentially stacked, and the inorganic insulating layers may include silicon nitride (SiNₓ), silicon oxide (SiOₓ), and silicon nitride (SiNₓ), respectively. However, embodiments are not limited thereto. For example, the pixel defining layer PDL may include a plurality of organic insulating layers, and the plurality of organic insulating layers may include at least one of polyimide, polyamide, acrylic resin, benzocyclobutene, and phenol resin.

The first, second, and third dam lower patterns DLP1, DLP2, DLP3 may be disposed on the passivation layer PVL at different distances from the display area DA. For example, the first, second, and third dam lower patterns DLP1, DLP2, DLP3 may be disposed on the passivation layer PVL in the non-display area NDA. The first, second, and third dam lower patterns DLP1, DLP2, DLP3 may be spaced apart from each other. The first, second, and third dam lower patterns DLP1, DLP2, DLP3 may be formed of the same material as the via layer VIL. Although three dam lower patterns are shown in FIG. 5, embodiments are not limited thereto. For example, the number of dam lower patterns may increase or decrease according to a process condition.

The first and second dam upper patterns DUP1 and DUP2 may be disposed on the second and third dam lower patterns DLP2 and DLP3, respectively. The first and second dam upper patterns DUP1 and DUP2 may be spaced apart from each other. The first and second dam upper patterns DUP1 and DUP2 may be formed of the same material as the pixel defining layer PDL.

In an embodiment, the first dam lower pattern DLP1 may be the only layer in a first dam structure DS1. However, embodiments are not limited thereto. For example, the first dam structure DS1 may further include a dam upper pattern such as the first and second dam upper patterns DUP1 and DUP2. The second dam lower pattern DLP2 and the first dam upper pattern DUP1 may configure the second dam structure DS2, and the third dam lower pattern DLP3 and the second dam upper pattern DUP2 may configure the third dam structure DS3. The first, second, and third dam structures DS1, DS2, DS3 may prevent an organic layer OL of the encapsulation layer TFE shown in FIG. 12 from spreading out. The first, second, and third dam structures DS1, DS2, DS3 may be spaced apart from each other. That is, since an organic layer such as the via layer VIL does not exist between the first, second, third dam structures DS1, DS2, DS3, penetration of an impurity, moisture, or the like through the organic layer in the non-display area NDA may be prevented.

The first support pattern SP1 may be disposed on the passivation layer PVL. For example, the first support pattern SP1 may be disposed on the passivation layer PVL in the non-display area NDA. The first support pattern SP1 may be disposed at the outermost portion of the non-display area NDA. The first support pattern SP1 may be spaced apart from the first, second, and third dam lower patterns DLP1, DLP2, DLP3. The first support pattern SP1 may be formed of the same material as the via layer VIL.

In an embodiment, a thickness of the first support pattern SP1 may be greater than a thickness of the first, second, and third dam lower patterns DLP1, DLP2, DLP3. A thickness may be a length measured in the third direction DR3.

The second support pattern SP2 may be disposed on the first support pattern SP1. The second support pattern SP2 may face the first support pattern SP1. For example, the second support pattern SP2 may be spaced apart from the first support pattern SP1 in the third direction DR3. The second support pattern SP2 may be formed of the same material as the pixel defining layer PDL.

In an embodiment, a width w2 of the second support pattern SP2 may be less than a width w1 of the first support pattern SP1. A width may be a length measured in the first direction DR1.

In some embodiments, the third support pattern SP3 may be disposed between the first support pattern SP1 and the second support pattern SP2. The third support pattern SP3 may be formed of the same material as the anode AE. The third support pattern SP3 may prevent the first support pattern SP1 from being reduced or damaged during an ashing process. For example, the third support pattern SP3 may block ashing gas from contacting the first support pattern SP1 and prevent the thickness of the first support pattern SP1 from decreasing. That is, the thickness of the first support pattern SP1 may be maintained constant by the third support pattern SP3.

The first, second, and third support patterns SP1, SP2, SP3 may make up a support structure SS. The support structure SS may serve to support a mask TM (refer to FIG. 6) used in deposition of the encapsulation layer TFE (refer to FIG. 4).

While the first, second, and third dam lower patterns DLP1, DLP2, DLP3 may be damaged or reduced in size during the ashing process, the first support pattern SP1 may not be damaged or reduced during the ashing process. As shown in FIG. 5, the thickness of the first, second, third dam lower patterns DLP1, DLP2, DLP3 on which the ashing process is performed may be less than the thickness of the first support pattern SP1. That is, while a thickness of the first, second, and third dam structures DS1 to DS3 decreases after the ashing process is performed, a thickness of the support structure SS may not decrease. Therefore, a predetermined thickness t1 of the support structure SS may be greater than the thickness of the first, second, and third dam structures DS1, DS2, DS3. The predetermined thickness t1 of the support structure SS may change according to a process condition.

Referring to FIGS. 5 and 6, when the thickness of the support structure SS supporting the mask TM decreases, a sagging phenomenon due to a load of the mask TM may occur, and thus a defect in which the mask TM contacts the pixel circuit layer PCL may occur. For example, when the first support pattern SP1 is reduced in size during the ashing process and the thickness of the support structure SS decreases from t1 to t2, a stab defect in which the circuit elements or the lines of the pixel circuit layer PCL are damaged due to the mask TM may occur. Experimentally, when the thickness of the support structure SS decreases by 1 μm, the defect rate may increase by 12 times.

Differently from FIG. 6, the thickness of the support structure SS shown in FIG. 5 may not decrease and may be maintained at the predetermined thickness t1 even after the ashing process. Therefore, the stab defect described above may be prevented, and thus the display device 100 (refer to FIG. 1) may operate normally.

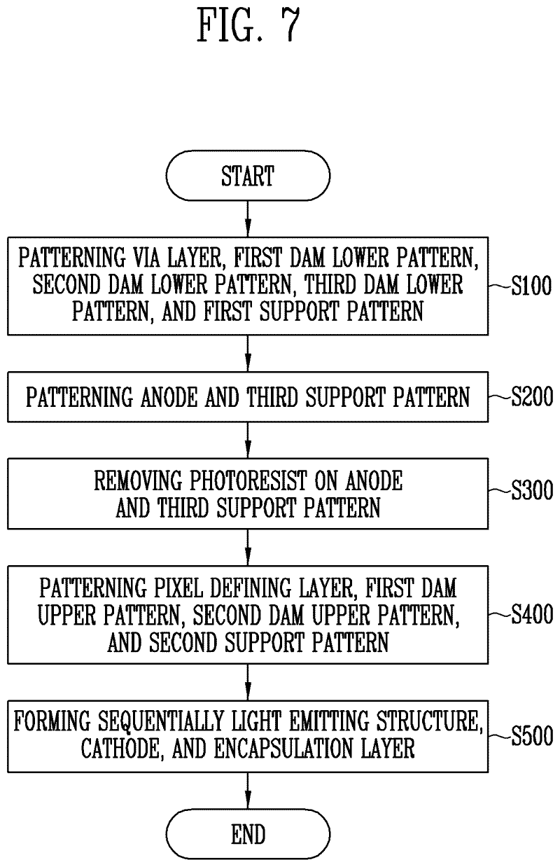

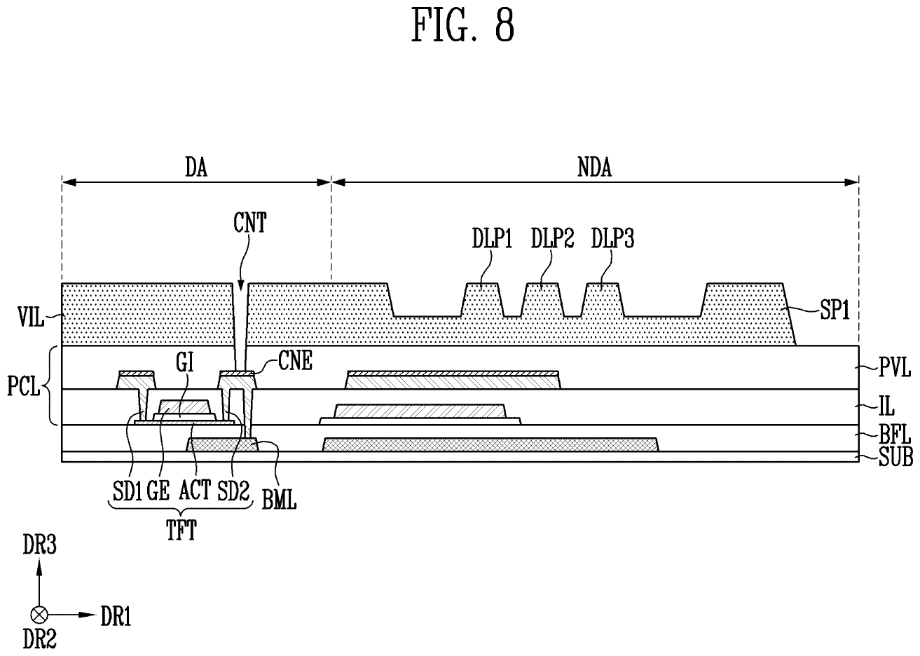

FIG. 7 is a flowchart illustrating a method of manufacturing a display device according to an embodiment. FIGS. 8 to 12 are cross-sectional views illustrating a method of manufacturing a display device according to an embodiment.

Prior to S100 process (operation), processes of depositing the lower metal layer BML, the buffer layer BFL, and the pixel circuit layer PCL on the substrate SUB may be preceded. Five masks may be used in these preceding processes. For example, the five masks may be used in patterning of the lower metal layer BML, patterning of the active pattern ACT, patterning of the gate electrode GE, patterning of the interlayer insulating layer IL, and patterning of the first and second electrodes SD1 and SD2, respectively.

Referring to FIGS. 7 and 8, the process S100 patterning the via layer VIL, the first dam lower pattern DLP1, the second dam lower pattern DLP2, the third dam lower pattern DLP3, and the first support pattern SP1 may be performed.

First, the via layer VIL may be deposited throughout the display area DA and the non-display area NDA. Thereafter, the via layer VIL may be patterned using a halftone mask. For example, the via layer VIL and the passivation layer PVL in the display area DA may be partially etched to pattern the via layer VIL including the contact hole CNT. Since the contact hole CNT extending through the via layer VIL and the passivation layer PVL are formed using one mask, the number of masks used in a manufacturing process may be reduced. In addition, the via layer VIL in the non-display area NDA may be etched to form the first dam lower pattern DLP1, the second dam lower pattern DLP2, the third dam lower pattern DLP3, and the first support pattern SP1 spaced apart from each other. As described above, the via layer VIL, the first dam lower pattern DLP1, the second dam lower pattern DLP2, the third dam lower pattern DLP3, and the first support pattern SP1 may be patterned through the same process.

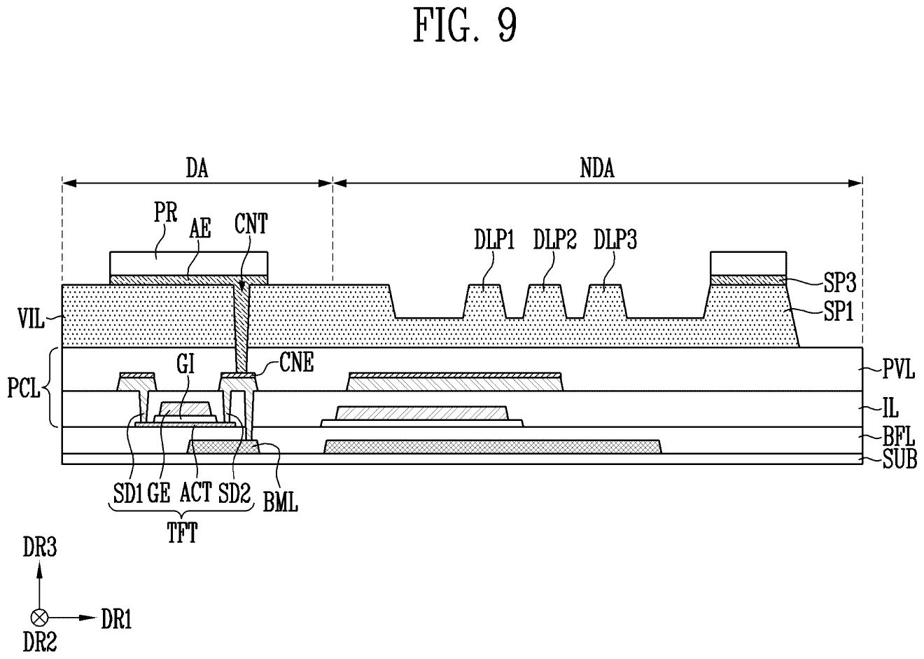

Referring to FIGS. 7 and 9, subsequently, a process S200 of patterning the anode AE and the third support pattern SP3 may be performed.

First, the anode AE may be deposited throughout the display area DA and the non-display area NDA. Thereafter, the photoresist PR may be applied on the anode AE and then the anode AE may be patterned using a mask. For example, the anode AE in the display area DA may be partially etched to pattern the anode AE connected to the connection electrode CNE through the contact hole CNT and electrically connected to the second electrode SD2 may be patterned. In addition, the anode AE in the non-display area NDA may be partially etched to pattern the third support pattern SP3 disposed on the first support pattern SP1. As described above, the anode AE and the third support pattern SP3 may be patterned through the same process. When the S200 process is performed, a photoresist PR may remain on the anode AE and the third support pattern SP3.

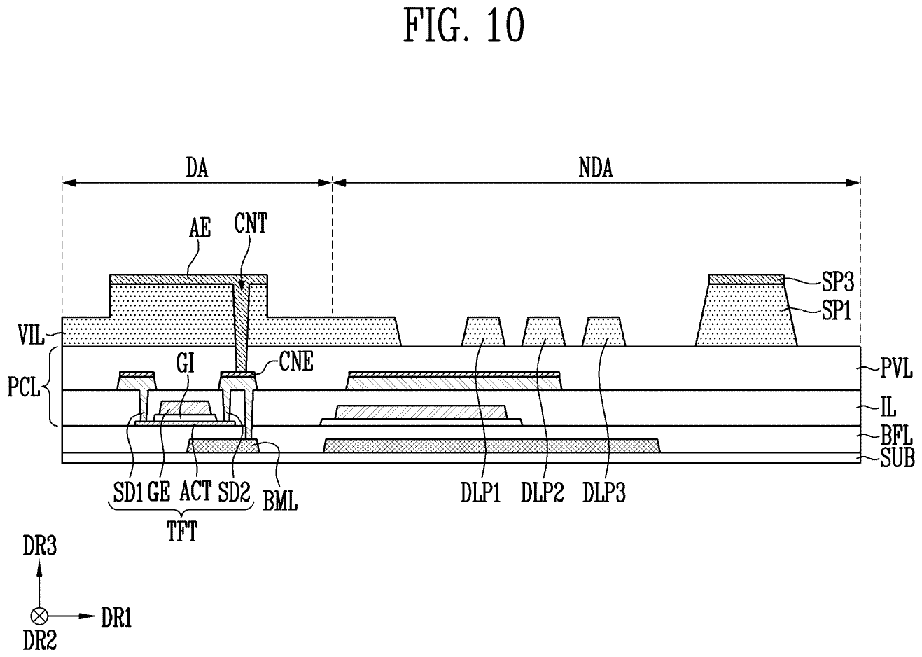

Referring to FIGS. 7 and 10, a process S300 of removing the photoresist PR (refer to FIG. 9) on the anode AE and the third support pattern SP3 may be performed. The S300 process may be referred to as an ashing process.

The ashing process may be performed in a wet method and/or a dry method. During the ashing process, not only are the photoresist PR on the anode AE and the third support pattern SP3 removed, but also the via layer VIL and the first, second, and third dam lower patterns DLP1, DLP2, DLP3 may be reduced in size or damaged. Accordingly, a step may be formed in the via layer VIL, and the thickness of the first, second, and third dam lower patterns DLP1, DLP2, DLP3 may be decreased. As for the first support pattern SP1, since it is covered by the third support pattern SP3 during the ashing process, the first support pattern SP1 may not be reduced in size and the thickness thereof may remain unchanged.

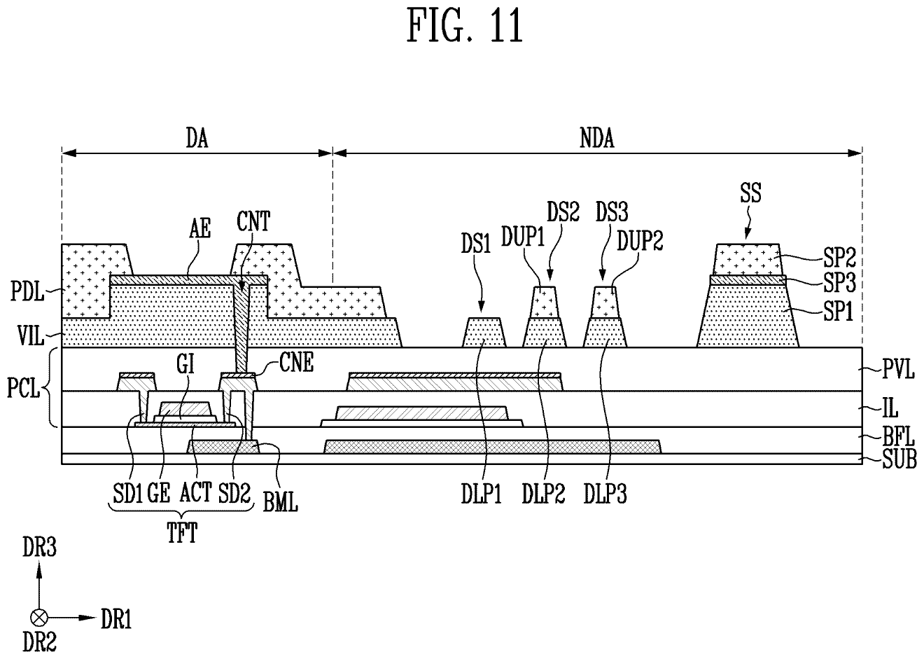

Referring to FIGS. 7 and 11, a process S400 of patterning the pixel defining layer PDL, the first dam upper pattern DUP1, the second dam upper pattern DUP2, and the second support pattern SP2 may be performed.

First, the pixel defining layer PDL may be deposited throughout the display area DA and the non-display area NDA. Thereafter, the pixel defining layer PDL may be patterned using a mask. For example, the pixel defining layer PDL in the display area DA may be partially etched to form an opening that partially exposes the anode AE. In addition, the pixel defining layer PDL in the non-display area NDA may be partially etched to form the first dam upper pattern DUP1 disposed on the second dam lower pattern DLP2, the second dam upper pattern DUP2 disposed on the third dam lower pattern DLP3, and the second support pattern SP2 disposed on the third support pattern SP3 through patterning. The pixel defining layer PDL, the first dam upper pattern DUP1, the second dam upper pattern DUP2, and the second support pattern SP2 may be patterned through the process that is described above.

At the end of the S400 process, the first dam structure DS1 including the first dam lower pattern DLP1, the second dam structure DS2 including second dam lower pattern DLP2 and the first dam upper pattern DUP1, and the third dam structure DS3 including the third dam lower pattern DLP3 and the second dam upper pattern DUP2 may be formed.

The processes that precede the S100 process and the processes S100 to S400 may be collectively referred to as a backplane process. As described above, the total of 5 masks may be used in the preceding processes and a total of 3 masks may be used in the processes S100 to S400. That is, a total of 8 masks may be used in the backplane process.

Referring to FIGS. 7 and 12, a process S500 of sequentially forming the light emitting structure EMS, the cathode CE, and the encapsulation layer TFE may be performed.

First, the light emitting structure EMS may be deposited on the anode AE and pixel defining layer PDL in the display area DA. The light emitting structure EMS may include at least one light emitting unit. For example, the light emitting unit may include a hole transport unit, a light emitting layer, and an electron transport unit sequentially disposed on the anode AE, but embodiments are not limited thereto.

Thereafter, the cathode CE may be deposited on the light emitting structure EMS. The cathode CE may be disposed on the pixel defining layer PDL and the via layer VIL in the non-display area NDA, and may be partially deposited on the passivation layer PVL in the non-display area NDA. The cathode CE may be a thin metal layer having a thickness sufficient to transmit light emitted from the light emitting structure EMS. The cathode CE may be formed of a metal material or a transparent conductive material to have a relatively thin thickness. For example, the cathode CE may include at least one of various transparent conductive materials including indium tin oxide, indium zinc oxide, indium tin zinc oxide, aluminum zinc oxide, gallium zinc oxide, zinc tin oxide, or gallium tin oxide, but embodiments are not limited thereto. For example, the cathode CE may include at least one of silver (Ag), magnesium (Mg), and a mixture thereof.

An exposed portion of the anode AE, a portion of the light emitting structure EMS on the anode AE, and a portion of the cathode CE on the light emitting structure EMS may be understood as configuring one light emitting element LD (refer to FIG. 2). Holes injected from the anode AE and electrons injected from the cathode CE may be transported into the light emitting layer of the light emitting structure EMS to form excitons, and light may be generated by the light emitting element LD when the excitons transit from an excited state to a ground state. A luminance of the light generated by the light emitting element LD may depend on the amount of a current flowing through the light emitting layer. The exact configuration of the light emitting layer determines a wavelength range of the light generated by the light emitting element LD.

Thereafter, the encapsulation layer TFE may be deposited on the cathode CE. In an embodiment, the encapsulation layer TFE may include a first inorganic layer IOL1, an organic layer OL, and a second inorganic layer IOL2.

First, the first inorganic layer IOL1 may be deposited on the cathode CE. The first inorganic layer IOL1 may be partially deposited on the passivation layer PVL in the non-display area NDA. In addition, the first inorganic layer IOL1 may be deposited to surround the first dam structure DS1 and the second dam structure DS2. In addition, the first inorganic layer IOL1 may be deposited to partially surround the third dam structure DS3. The first inorganic layer IOL1 may include silicon nitride (SiNₓ), silicon oxide (SiOₓ), silicon oxynitride (SiOₓN_{y}), or the like, but embodiments are not limited thereto.

Thereafter, the organic layer OL may be deposited on the first inorganic layer IOL1. The organic layer OL may be partially deposited on the first inorganic layer IOL1 in the non-display area NDA. During deposition, the organic layer OL is prevented from spreading to an area outside of the non-display area NDA by the first, second, and third dam structures DS1 to DS3. The organic layer OL may include an organic insulating material such as acrylic resin (polyacrylates resin), epoxy resin, phenolic resin, polyamides resin, polyimides resin, unsaturated polyester resin, poly-phenylene ethers resin, poly-phenylene sulfides resin, or benzocyclobutene resin, but embodiments are not limited thereto.

Thereafter, the second inorganic layer IOL2 may be deposited on the organic layer OL. The second inorganic layer IOL2 may include the same material as the first inorganic layer IOL1 or may include one or more materials selected from the material exemplified as the configuration material of the first inorganic layer IOL1.

As described above, since the support structure SS is not reduced in size or damaged during the backplane process and the thickness thereof is maintained, a stab defect of the mask TM (refer to FIG. 6) may not occur during a process of depositing the encapsulation layer TFE.

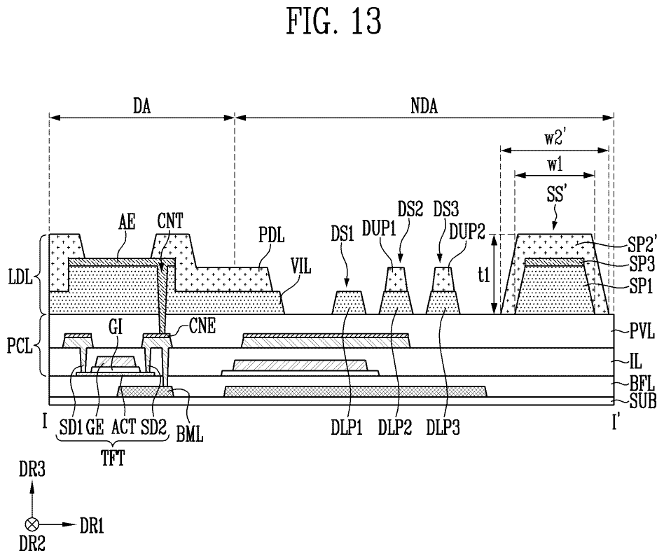

FIG. 13 is a cross-sectional view taken along line I-I′ of FIG. 3 according to an embodiment. Regarding FIG. 13, any description that was already provided above (e.g., in reference to FIG. 5) is abbreviated or omitted to avoid redundancy.

Referring to FIG. 13, a support structure SS′ may include the first support pattern SP1, a second support pattern SP2′, and the third support pattern SP3. In an embodiment, a width w2′ of the second support pattern SP2′ may be greater than the width w1 of the first support pattern SP1. For example, the second support pattern SP2′ may extend beyond the edges of the third support pattern SP3 and may be disposed on the passivation layer PVL in the non-display area NDA. In this case, the second support pattern SP2′ may surround the first support pattern SP1 and the third support pattern SP3. The second support pattern SP2′ may prevent the third support pattern SP3 from being exposed, thereby preventing a defect in which a metal component of the third support pattern SP3 is eluted.

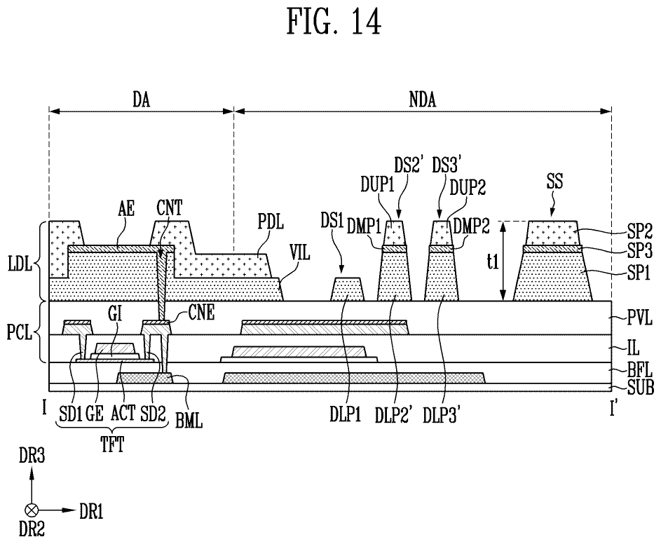

FIG. 14 is a cross-sectional view taken along line I-I′ of FIG. 3 according to an embodiment. Regarding FIG. 14, any description that is provided above (e.g. in reference to FIG. 5) is abbreviated or omitted to avoid redundancy.

Referring to FIG. 14, a second dam structure DS2′ may include a second dam lower pattern DLP2′, the first dam upper pattern DUP1, and a first dam center pattern DMP1 disposed between the second dam lower pattern DLP2′ and the first dam upper pattern DUP1. The first dam center pattern DMP1 may be formed of the same material as the anode AE. That is, the first dam center pattern DMP1 and the anode AE may be patterned through the same process.

A third dam structure DS3′ may include a third dam lower pattern DLP3′, the second dam upper pattern DUP2, and a second dam center pattern DMP2 disposed between the third dam lower pattern DLP3′ and the second dam upper pattern DUP2. The second dam center pattern DMP2 may be formed of the same material as the anode AE. That is, the second dam center pattern DMP2 and the anode AE may be patterned through the same process.

The first and second dam center patterns DMP1 and DMP2 may prevent the second and third dam lower patterns DLP2′ and DLP3′ from being reduced in size during the ashing process, respectively. For example, the first and second dam center patterns DMP1 and DMP2 may block ashing gas from contacting the second and third dam lower patterns DLP2′ and DLP3′, respectively, to prevent a thickness of the second and third dam lower patterns DLP2′ and DLP3′ from decreasing. That is, the thickness of the second and third dam lower patterns DLP2′ and DLP3′ may be maintained constant by the first and second dam center patterns DMP1 and DMP2.

In an embodiment, the thickness of the first support pattern SP1 may be greater than a thickness of the first dam lower pattern DLP1 and may be equal to the thickness of the second and third dam lower patterns DLP2′ and DLP3′.

Similarly to the first support pattern SP1, the second and third dam lower patterns DLP2′ and DLP3′ may not be reduced in size during the ashing process. As shown in FIG. 14, the thickness of the second and third dam lower patterns DLP2′ and DLP3′ on which the ashing process is performed may be equal to the thickness of the first support pattern SP1. Therefore, the thickness t1 of the support structure SS may be equal to a thickness of the second and third dam structures DS2′ and DS3′.

Although not explicitly illustrated, according to an embodiment, a dam center pattern such as the first and second dam center patterns DMP1 and DMP2 may be disposed on the first dam lower pattern DLP1. In addition, a dam upper pattern such as the first and second dam upper patterns DUP1 and DUP2 may be disposed on the dam center pattern to make the first dam structure DS1 similarly structured as the second dam structure DS2′ and the third dam structure DS3′.

Although not explicitly illustrated, according to an embodiment, one of the first and second dam center patterns DMP1 and DMP2 may be omitted.

A display device according to an embodiment is applicable to various types of electronic devices. In an embodiment, an electronic device includes the above-described display device and may further include other modules or devices having additional functions in addition to the display device.

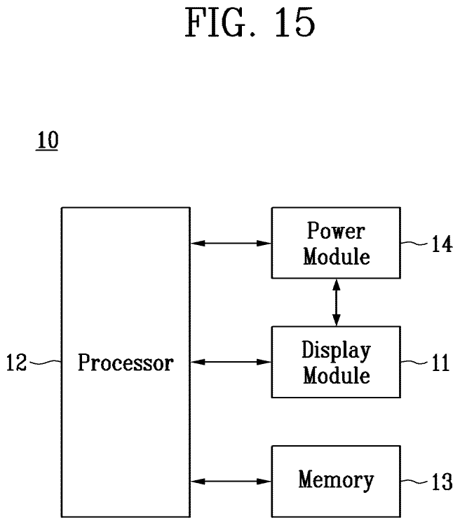

FIG. 15 is a block diagram of an electronic device according to an embodiment. Referring to FIG. 15, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

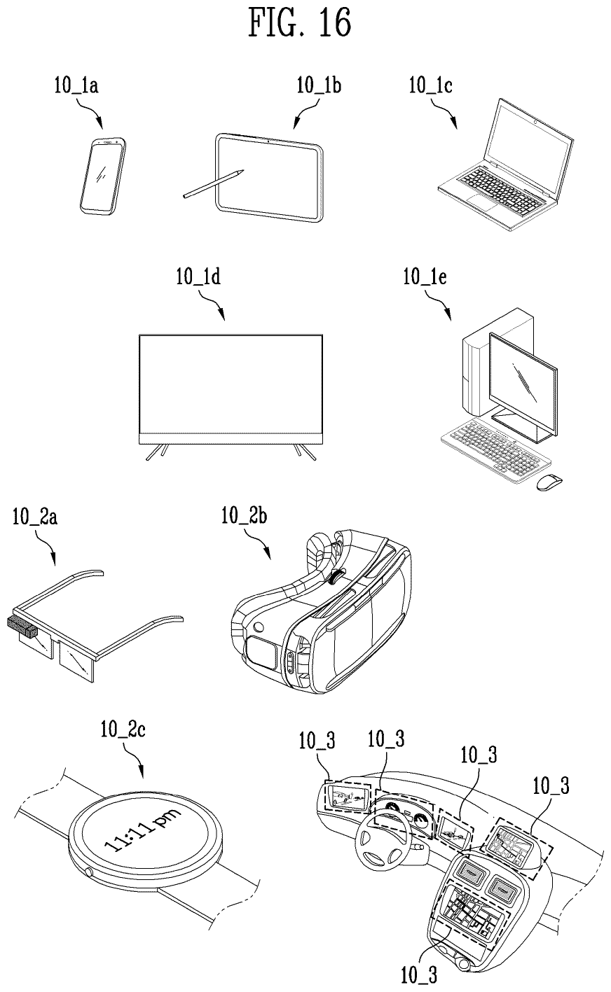

FIG. 16 shows schematic views of various embodiments of an electronic device.

Referring to FIG. 16, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Although the disclosure has been specifically described according to the above-described embodiments, it should be noted that the above-described embodiments are for describing the disclosure and not for limiting the scope of the disclosure. Those of ordinary skill in the art to which the disclosure pertains will understand that various modifications are possible within the scope of the technical spirit of the disclosure.

The scope of the disclosure is not limited to the details described in the detailed description of the specification, but should be defined by the claims. In addition, it is to be construed that all changes or modifications derived from the meaning and scope of the claims and equivalent concepts thereof are included in the scope of the disclosure.

What is claimed is:

1. A display device comprising:
a substrate including a display area and a non-display area;
a pixel circuit layer disposed on the substrate; and
a support structure disposed on the pixel circuit layer in the non-display area,
wherein the support structure comprises:
a first support pattern;
a second support pattern on the first support pattern; and
a third support pattern disposed between the first support pattern and the second support pattern.

2. The display device according to claim 1, further comprising:
a first dam structure, a second dam structure, and a third dam structure disposed on the pixel circuit layer in the non-display area and spaced apart from each other.

3. The display device according to claim 2, wherein:
the first dam structure includes a first dam lower pattern,
the second dam structure includes a second dam lower pattern and a first dam upper pattern disposed on the second dam lower pattern, and
the third dam structure includes a third dam lower pattern and a second dam upper pattern disposed on the third dam lower pattern.

4. The display device according to claim 3, further comprising:
a via layer disposed on the pixel circuit layer in the display area;
an anode disposed on the via layer and extending through a portion of the pixel circuit layer and the via layer; and
a pixel defining layer disposed on a portion of the anode and the via layer.

5. The display device according to claim 4, wherein the first, second, and third dam lower patterns and the first support pattern are formed of the same material as the via layer,
the first and second dam upper patterns and the second support pattern are formed of the same material as the pixel defining layer, and
the third support pattern is formed of the same material as the anode.

6. The display device according to claim 5, wherein a thickness of the support structure is greater than a thickness of the first, second, and third dam structures.

7. The display device according to claim 6, wherein a thickness of the first support pattern is greater than a thickness of the first, second, and third dam lower patterns.

8. The display device according to claim 7, wherein a width of the second support pattern is less than a width of the first support pattern.

9. The display device according to claim 7, wherein a width of the second support pattern is greater than a width of the first support pattern.

10. The display device according to claim 9, wherein the second support pattern surrounds the first support pattern and the third support pattern.

11. The display device according to claim 5, wherein the second dam structure further includes a first dam center pattern disposed between the second dam lower pattern and the first dam upper pattern, and
the third dam structure further includes a second dam center pattern disposed between the third dam lower pattern and the second dam upper pattern.

12. The display device according to claim 11, wherein a thickness of the support structure is greater than a thickness of the first dam structure and is equal to a thickness of the second and third dam structures.

13. The display device according to claim 12, wherein a thickness of the first support pattern is greater than a thickness of the first dam lower pattern and is equal to a thickness of the second and third lower patterns.

14. The display device according to claim 11, wherein the first and second dam center patterns are formed of the same material as the anode.

15. A method of manufacturing a display device, the method comprising:
patterning a via layer that is on a pixel circuit layer in a display area, and patterning a first dam lower pattern, a second dam lower pattern, a third dam lower pattern, and a first support pattern on the pixel circuit layer in a non-display area;
patterning a portion of the pixel circuit layer and an anode extending through the via layer on the via layer and patterning a third support pattern on the first support pattern;
removing a first photoresist on the anode and a second photoresist on the third support pattern; and
patterning a pixel defining layer on a portion of the anode and the via layer, patterning a first dam upper pattern on the second dam lower pattern, patterning a second dam upper pattern on the third dam lower pattern, and patterning a second support pattern on the third support pattern.

16. The method according to claim 15, wherein after removing the first photoresist and the second photoresist, a thickness of the first support pattern is greater than a thickness of the first, second, and third dam lower patterns.

17. The method according to claim 16, wherein a width of the second support pattern is less than a width of the first support pattern.

18. The method according to claim 16, wherein a width of the second support pattern is greater than a width of the first support pattern.

19. The method according to claim 18, wherein the second support pattern surrounds the first support pattern and the third support pattern.

20. The method according to claim 15, further comprising:
patterning a first dam center pattern positioned between the second dam lower pattern and the first dam upper pattern and patterning a second dam center pattern positioned between the third dam lower pattern and the second dam upper pattern,
wherein after removing the first photoresist and the second photoresist, a thickness of the first support pattern is greater than a thickness of the first dam lower pattern and is equal to a thickness of the second and third dam lower patterns.

21. An electronic device comprising:
a processor to provide input image data; and
a display device to display an image based on the input image data,
wherein the display device comprises:
a substrate including a display area and a non-display area;
a pixel circuit layer disposed on the substrate; and
a support structure disposed on the pixel circuit layer in the non-display area, and
wherein the support structure comprises:
a first support pattern;
a second support pattern on the first support pattern; and
a third support pattern disposed between the first support pattern and the second support pattern.

22. The electronic device according to claim 21, wherein the display device further comprises:
a first dam structure, a second dam structure, and a third dam structure disposed on the pixel circuit layer in the non-display area and spaced apart from each other.

23. The electronic device according to claim 22, wherein:
the first dam structure includes a first dam lower pattern,
the second dam structure includes a second dam lower pattern and a first dam upper pattern disposed on the second dam lower pattern, and
the third dam structure includes a third dam lower pattern and a second dam upper pattern disposed on the third dam lower pattern.

24. The electronic device according to claim 23, wherein the display device further comprises:
a via layer disposed on the pixel circuit layer in the display area;
an anode disposed on the via layer and extending through a portion of the pixel circuit layer and the via layer; and
a pixel defining layer disposed on a portion of the anode and the via layer.

25. The electronic device according to claim 24, wherein the first, second, and third dam lower patterns and the first support pattern are formed of the same material as the via layer,
the first and second dam upper patterns and the second support pattern are formed of the same material as the pixel defining layer, and
the third support pattern is formed of the same material as the anode.
